(19) United States
(12) Patent Application Publication
(10) Pub. No.: US 2026/0165193 A1
(43) Pub. Date: Jun. 11, 2026

(54) STRUCTURE ON SUBSTRATE AND METHOD OF MANUFACTURING STRUCTURE ON SUBSTRATE

(71) Applicant: Mitsubishi Electric Corporation, Tokyo (JP)

(72) Inventor: Takakazu MARUYAMA, Tokyo (JP)

(73) Assignee: Mitsubishi Electric Corporation, Tokyo (JP)

(21) Appl. No.: 19/321,095

(22) Filed: Sep. 5, 2025

(30) Foreign Application Priority Data
Dec. 10, 2024 (JP) 2024-215260

(51) Int. Cl. H01L 23/31; H01L 21/288; H01L 21/56; H01L 23/29; H10D 12/00; H10D 30/66

(52) U.S. Cl. CPC H10W 74/137; H10P 14/47; H10W 74/01; H10W 74/147; H10W 74/47; H10D 12/441; H10D 30/66

(57) ABSTRACT

A structure on a substrate according to the present disclosure includes a substrate, a copper plating layer provided on the substrate, a cap film covering the copper plating layer and containing a diffusion preventing component for preventing diffusion of copper, and a resin film provided on the cap film.

### BACKGROUND

### Technical Field

The present disclosure relates to a structure on a substrate, and particularly relates to a structure on a substrate including a protective film.

### Description of the Background Art

In recent years, polyimide has been used as a protective film in semiconductor devices and printed circuit boards. Polyimide has high heat resistance performance at a heat resistance temperature of 450° C. or higher, high thermal conductivity, and excellent thermal characteristics. In addition, polyimide has a dielectric constant, volume resistivity, and the like, that hardly change from a cryogenic temperature to 300° C., and is excellent in electrical characteristics. In addition, polyimide has a small coefficient of thermal expansion, a low coefficient of thermal shrinkage, and high dimensional stability, and is excellent in flame retardancy, is hardly flammable, is not dissolved in most organic solvents, has high chemical resistance even at high temperatures, and is excellent in mechanical properties.

However, in a case where a copper material and polyimide are in contact with each other, there is a problem that heat resistance and peeling strength are deteriorated. This is because polyimide is oxidatively decomposed by catalytic action of copper at an interface between polyimide and the copper material, thereby cuprous oxide is generated and diffused.

In order to suppress this, for example, Japanese Patent Application Laid-Open No. 2014-212225 discloses a technique of using a rust inhibitor containing a benzotriazole-based material or a rust inhibitor containing an imidazole-based material as a rust preventive film for copper or a copper compound.

The rust inhibitor disclosed in Japanese Patent Application Laid-Open No. 2014-212225 is applied by a spin coater for the purpose of applying the rust inhibitor to the whole. However, the rust inhibitor is treated for each sheet, and thus, there is a problem that cost increases. This similarly applies to a case where chemical vapor deposition (CVD) processing, which is a general method, is used.

### SUMMARY

An object of the present disclosure is to provide a structure on a substrate in which peeling of a protective film is suppressed, and reliability is improved.

A structure on a substrate according to the present disclosure includes a substrate, a copper plating layer provided on the substrate, a cap film covering the copper plating layer and containing a diffusion preventing component for preventing diffusion of copper, and a resin film provided on the cap film.

According to the structure on the substrate of the present disclosure, by providing the cap film so as to cover a surface of the copper plating layer and providing the resin film thereon, it is possible to prevent diffusion of copper, suppress peeling of the resin film, and improve reliability of the structure on the substrate.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating an example of an overall configuration of a MOS transistor to which a structure on a substrate according to the present disclosure is applied;

FIG. 2 is a schematic cross-sectional view of a semiconductor device to which the structure on the substrate of a first preferred embodiment is applied;

FIG. 3 is a flowchart for explaining a method of manufacturing the semiconductor device to which the structure on the substrate of the first preferred embodiment is applied;

FIG. 4 is a cross-sectional view illustrating a manufacturing process of the semiconductor device to which the structure on the substrate of the first preferred embodiment is applied;

FIG. 5 is a cross-sectional view illustrating a manufacturing process of the semiconductor device to which the structure on the substrate of the first preferred embodiment is applied;

FIG. 6 is a cross-sectional view illustrating a manufacturing process of the semiconductor device to which the structure on the substrate of the first preferred embodiment is applied;

FIG. 7 is a cross-sectional view illustrating a manufacturing process of the semiconductor device to which the structure on the substrate of the first preferred embodiment is applied;

FIG. 8 is a conceptual diagram illustrating a manufacturing process of the semiconductor device to which the structure on the substrate of the first preferred embodiment is applied;

FIG. 9 is a cross-sectional view illustrating a manufacturing process of the semiconductor device to which the structure on the substrate of the first preferred embodiment is applied;

FIG. 10 is a schematic cross-sectional view of a semiconductor device to which a structure on a substrate of a second preferred embodiment is applied;

FIG. 11 is a flowchart for explaining a method of manufacturing the semiconductor device to which the structure on the substrate of the second preferred embodiment is applied;

FIG. 12 is a cross-sectional view illustrating a manufacturing process of the semiconductor device to which the structure on the substrate of the second preferred embodiment is applied;

FIG. 13 is a conceptual diagram illustrating a manufacturing process of the semiconductor device to which the structure on the substrate of the second preferred embodiment is applied;

FIG. 14 is a plan view illustrating a manufacturing process of the semiconductor device to which the structure on the substrate of the second preferred embodiment is applied;

FIG. 15 is a cross-sectional view illustrating a manufacturing process of the semiconductor device to which the structure on the substrate of the second preferred embodiment is applied;

FIG. 16 is a perspective plan view illustrating an example in which the structure on the substrate of the second preferred embodiment is applied to a printed circuit board;

FIG. 17 is a perspective plan view illustrating an example in which the structure on the substrate of the second preferred embodiment is applied to a printed circuit board;

FIG. 18 is a perspective plan view illustrating an example in which the structure on the substrate of the second preferred embodiment is applied to a printed circuit board; and

FIG. 19 is a conceptual diagram illustrating a manufacturing apparatus for a structure on a substrate of a third preferred embodiment.

### DESCRIPTION OF THE PREFERRED EMBODIMENTS

### Introduction

Hereinafter, preferred embodiments according to the present disclosure will be described with reference to the accompanying drawings. Note that the drawings schematically illustrate components, and a mutual relationship of sizes and positions of the components illustrated in different drawings is not necessarily accurately described, and can be appropriately changed. Furthermore, in the following description, similar components are denoted by the same reference numerals, and names and functions thereof are also similar. Thus, detailed description thereof may be omitted.

In addition, in the following description, terms meaning specific positions and directions such as “upper”, “lower”, “side”, “front”, and “back” may be used, but these terms are used for convenience to facilitate understanding of the content of the preferred embodiments and are not related to directions when actually implemented. In addition, in the following description, “outside” is a direction toward an outer periphery of a semiconductor device, and “inside” is a direction opposite to “outside”.

In addition, the term “MOS” has been used for a metal-oxide-semiconductor junction structure in the past, and is an acronym for Metal-Oxide-Semiconductor. However, particularly in a field effect transistor having a MOS structure (hereinafter, simply referred to as a “MOS transistor”), materials of a gate insulating film and a gate electrode have been improved from the viewpoint of recent integration, improvement of a manufacturing process, and the like. Thus, the term “MOS” is not necessarily adopted with a limitation only on the metal-oxide-semiconductor stacked structure, and such a limitation is not assumed in the present specification.

### First Preferred Embodiment

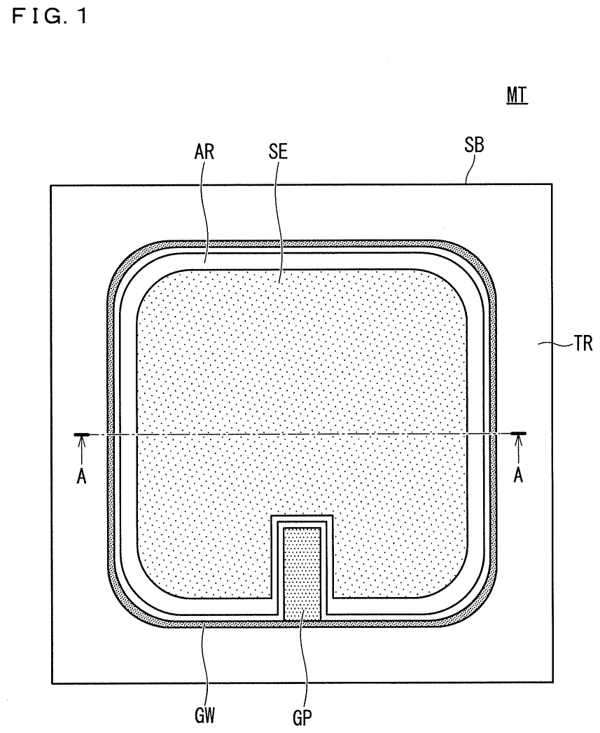

FIG. 1 is a plan view illustrating an example of an overall configuration of a MOS transistor MT to which a structure on a substrate according to the present disclosure is applied. As illustrated in FIG. 1, the MOS transistor MT includes a rectangular semiconductor substrate SB, and a central portion of the MOS transistor MT is an active region AR through which a main current flows in an on state. A plan view shape of the active region AR has a rectangular shape in which four corners have curvatures, a central portion of one side of the rectangular shape is recessed inward in a rectangular shape, and a gate pad GP is provided so as to enter the portion recessed inward of the active region AR. In addition, a source electrode SE having substantially the same size and shape as the active region AR is provided on the active region AR.

In addition, a gate wiring GW connected to one side of the gate pad GP is provided along an outer periphery of the active region AR, and the active region AR is surrounded by the gate wiring GW. Note that arrangement and plan view shapes of the active region AR, the source electrode SE, and the gate pad GP are not limited to the above. A region from an outer edge of the gate wiring GW to an outer edge of the semiconductor substrate SB is defined as a termination region TR.

### Device Configuration

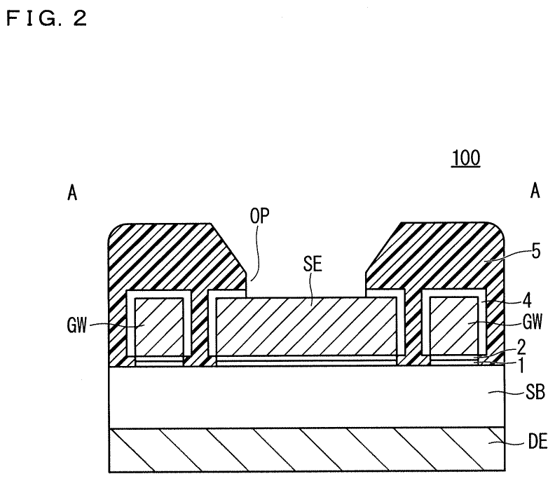

FIG. 2 is a schematic cross-sectional view of a region indicated by a line A-A in FIG. 1. For the sake of simplicity, FIG. 2 illustrates a ratio in a plane direction and a thickness direction different from that in FIG. 1, and various semiconductor regions formed in the active region AR are also omitted. In addition, the structure on the substrate according to the present disclosure is not limited to application to a MOS transistor, and can also be applied to an insulated gate bipolar transistor (IGBT) and a reverse conducting IGBT (RC-IGBT), and thus, FIG. 2 illustrates a case where the structure on the substrate is applied to a semiconductor device 100.

As illustrated in FIG. 2, in the semiconductor device 100, the source electrode SE and the gate wiring GW are provided on the semiconductor substrate SB via a sputtering protective film 1 and a seed film 2. A cap film 4 for surface protection is provided on a partial surface of the source electrode SE and a surface of the gate wiring GW, and a portion where the cap film 4 is provided is covered with a polyimide film 5. A drain electrode DE also functioning as a back metal is provided on the back surface side of the semiconductor substrate SB opposite to the source electrode SE.

### Manufacturing Method

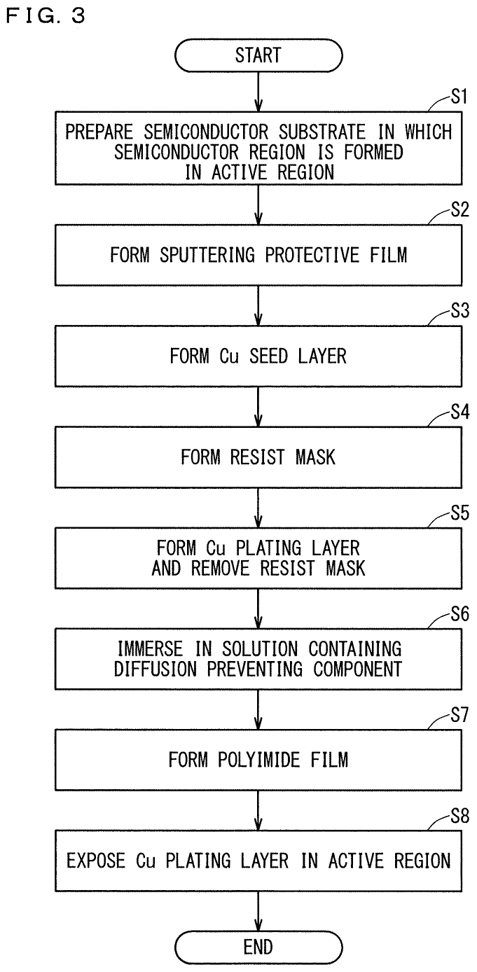

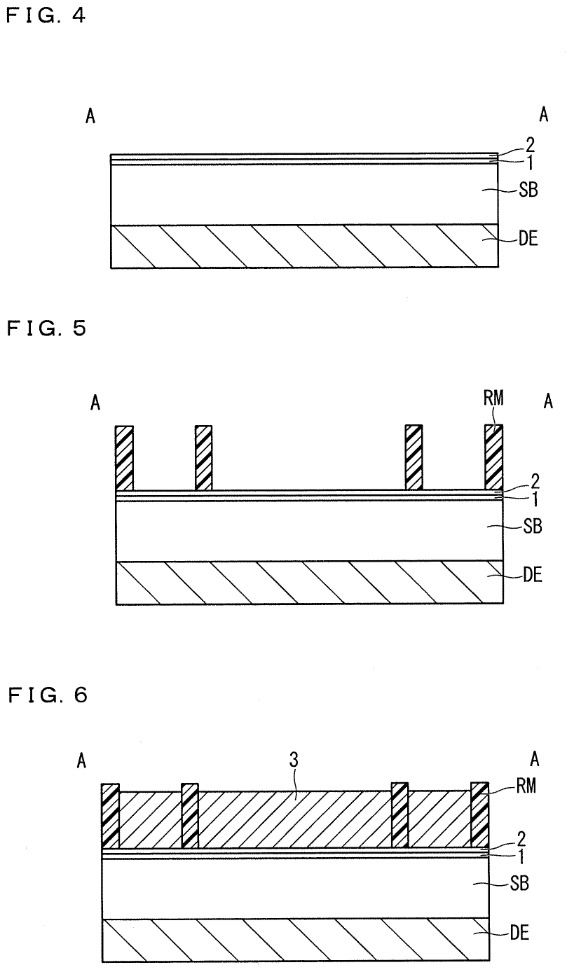

Next, a method of manufacturing the semiconductor device 100 will be described with reference to FIGS. 1 and 4 to 9 with reference to the flowchart indicated in FIG. 3. Note that the processes illustrated in FIGS. 4 to 9 are processes in a wafer state, but are represented as one semiconductor chip for convenience.

First, as illustrated in FIG. 4, the semiconductor substrate SB in which a semiconductor region is formed in the active region AR is prepared (step S1). In FIG. 4, the drain electrode DE is formed on the back surface of the semiconductor substrate SB, but the drain electrode DE can be formed at a later timing.

Next, as illustrated in FIG. 4, the sputtering protective film 1 is formed on the main surface opposite to the drain electrode DE side, of the semiconductor substrate SB (step S2). The sputtering protective film 1 is formed with any film of titanium nitride (TiN), titanium (Ti), and tetraethoxysilane (TEOS), or a laminated film of a plurality of films, and functions as a protective film when the seed film 2 is formed by sputtering.

Next, as illustrated in FIG. 4, the seed film 2 of Ti and copper (Cu) is formed on the sputtering protective film 1 by sputtering (step S3). The seed film 2 has a function of increasing adhesion with a lower layer when a copper film is formed by plating, and also has a role as a barrier metal for preventing diffusion of copper.

In the process illustrated in FIG. 5, a resist film is formed on the seed film 2 and patterned by photolithography to form a resist mask RM (step S4). Here, an example of using a negative resist material is illustrated.

Next, in the process illustrated in FIG. 6, the copper plating layer 3 is formed by copper plating in an opening of the resist mask RM (step S5). For copper plating, electroless plating or electrolytic plating can be used.

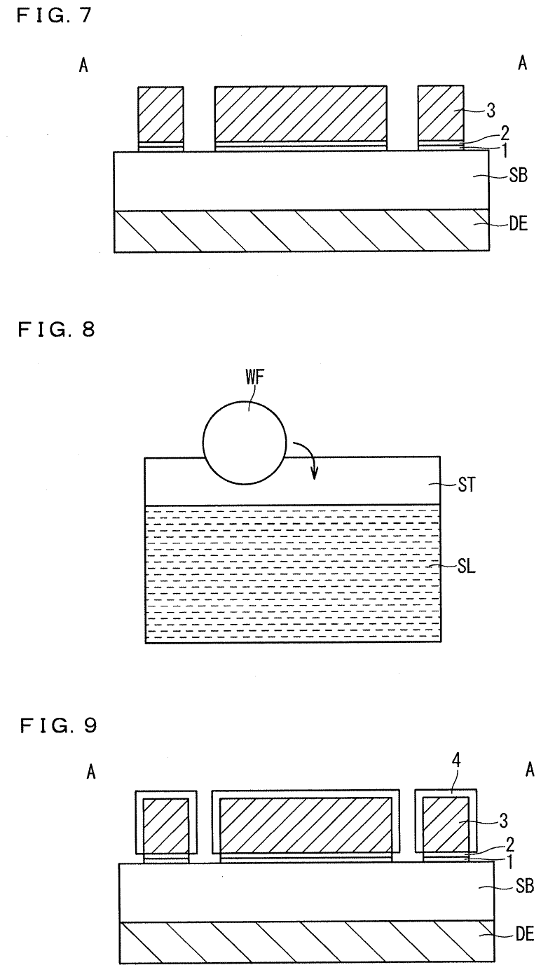

After the copper plating layer 3 is formed, the resist mask RM is removed, and the seed film 2 and the sputtering protective film 1 at a portion where the resist mask RM has been formed are removed in the process illustrated in FIG. 7. Note that the technique known in the related art can be used for removing the resist mask RM, the seed film 2, and the sputtering protective film 1.

Next, in the process illustrated in FIG. 8, a wafer WF in a state where the copper plating layer 3 is formed on the semiconductor substrate SB is immersed in a solution SL containing a diffusion preventing component in a processing tank ST to perform capping processing (step S6).

As the diffusion preventing component, an organic inhibitor can be used, and a long-chain alkyl sulfur compound such as a mercapto compound (R—SH) or a thiourea compound (R₂N—C (═S)—NR′₂) can be selected. In the above chemical formula, R represents an alkyl group (—CₙH₂ₙ₋₁).

As a mechanism capable of preventing diffusion, the organic inhibitor forms a strong adsorption bond with copper. In other words, by reinforcing a weak point of a surface oxide film and forming an inactive film on the oxide film after adsorption, the film becomes a physical protective barrier and functions as a capping film.

Here, returning to the description of the flowchart of FIG. 3, the wafer WF is immersed in the solution SL containing the diffusion preventing component, and then the wafer WF is cleaned with pure water and dried to form the cap film 4 on the surface of the copper plating layer 3 as illustrated in FIG. 9. The diffusion preventing component is washed away with pure water in a portion other than the copper material, but is easily attached to the copper material, and thus remains as the cap film 4 on the surface of the copper material.

Next, the polyimide film 5 is formed on the copper plating layer 3 on which the cap film 4 is formed (step S7), and the polyimide film 5 is selectively removed together with the cap film 4 so that the polyimide film 5 remains only in a necessary portion, thereby exposing the copper plating layer 3 on the active region AR, that is, the source electrode SE, to obtain the semiconductor device 100 illustrated in FIG. 2 (step S8).

### Effects

In the semiconductor device 100 according to the first preferred embodiment described above, the cap film 4 can be formed by immersing the wafer WF with the copper plating layer 3 formed on the semiconductor substrate SB in the solution SL containing the diffusion preventing component, so that the cap film 4 can be easily formed and the cost can be reduced as compared with the capping method in the related art. For example, as the technique in the related art, there is a method of forming a cap film on a copper material by chemical vapor deposition (CVD), physical vapor deposition (PVD), or the like. However, in order to use these methods, vacuuming in a vacuum container is required, and application is performed only in a predetermined range. Thus, these methods are not applied to mass production. However, in the method according to the present disclosure, it is only necessary to immerse the wafer in a solution containing a diffusion preventing component, so that a processing apparatus is simplified, processing can be performed at a time, mass productivity is enhanced, and a unit price per one wafer is reduced. Also in the composite pattern, capping can be performed on the entire surface including a side surface portion of the copper material.

In addition, by forming the cap film 4 on the surface of the copper material, it is possible to suppress oxidative decomposition at an interface due to contact between the resin material containing the polyimide film and the copper material and suppress oxidation reaction of copper, so that it is possible to obtain a structure on a substrate in which diffusion of a copper component is prevented, peeling of the resin material is suppressed, and reliability is improved.

### Modifications

In the above description, an example in which an organic inhibitor is used as the diffusion preventing component has been described, but a solution containing an inorganic inhibitor or a metal-containing material such as silver (Ag) can also be used as the diffusion preventing component.

As the inorganic inhibitor, for example, phosphate compounds such as hexametaphosphate, sodium metaphosphate, nitrite, nitrate, chromate, molybdate, technetate, and vanadate can be selected. By using the inorganic inhibitor, the diffusion preventing component can be directly adsorbed to the metal surface to perform capping.

As the metal-containing material, an Sn-Ag plating solution, an Ag electroless solution, an Ag electrolytic solution, and the like, can be selected. In a case where Ag is contained, silver is sufficiently recrystallized by heat at about 150° C. at which oxidative decomposition of the resin occurs after substitution with the copper surface, and thus, the metal-containing material functions as a copper capping film.

As the metal to be contained, in addition to Ag, a metal having lower ionization tendency than copper, gold (Au), platinum (Pt), mercury (Hg), and the like, can be used.

By immersing the wafer WF on which the copper plating layer 3 is formed in a solution containing these, substitution reaction occurs, the surface metal is covered with a metal having low ionization tendency, and functions as the cap film 4.

In addition, although ionization tendency is higher than that of copper, iron (Fe), or the like, acts as a sacrificial anode to form a corrosion prevention and protective film.

Even in a case where a solution containing an inorganic inhibitor or a metal-containing material such as silver (Ag) is used, the cap film 4 can be formed by immersing the wafer WF, so that the cap film 4 can be easily formed, and the cost can be reduced as compared with the capping method in the related art.

In addition, in the case of the inorganic inhibitor, temperature stability is high, so that it is possible to prevent oxidative decomposition at the interface due to contact between the resin and copper and to prevent oxidation reaction of copper.

Further, in a case where a solution containing a metal-containing material is used, catalytic action of copper is eliminated, so that oxidative decomposition at the contact interface between the resin and copper can be prevented.

### Second Preferred Embodiment

### Device Configuration

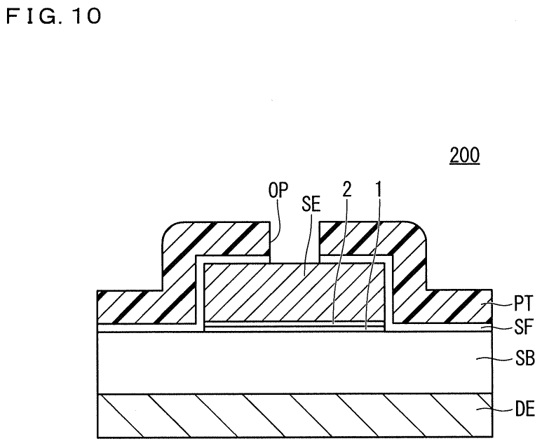

FIG. 10 is a cross-sectional view illustrating a semiconductor device 200 of a second preferred embodiment. Note that, although the semiconductor device 200 is basically the same as the semiconductor device 100 illustrated in FIG. 2, FIG. 10 is made more simplified and, only the source electrode SE is illustrated. Note that the same components as those of the semiconductor device 100 are denoted by the same reference numerals, and redundant description will be omitted.

As illustrated in FIG. 10, in the semiconductor device 200, the cap film SF containing a diffusion preventing component is provided on a partial surface of the source electrode SE and its periphery, and a polyimide tape PT is provided on the cap film SF.

### Manufacturing Method

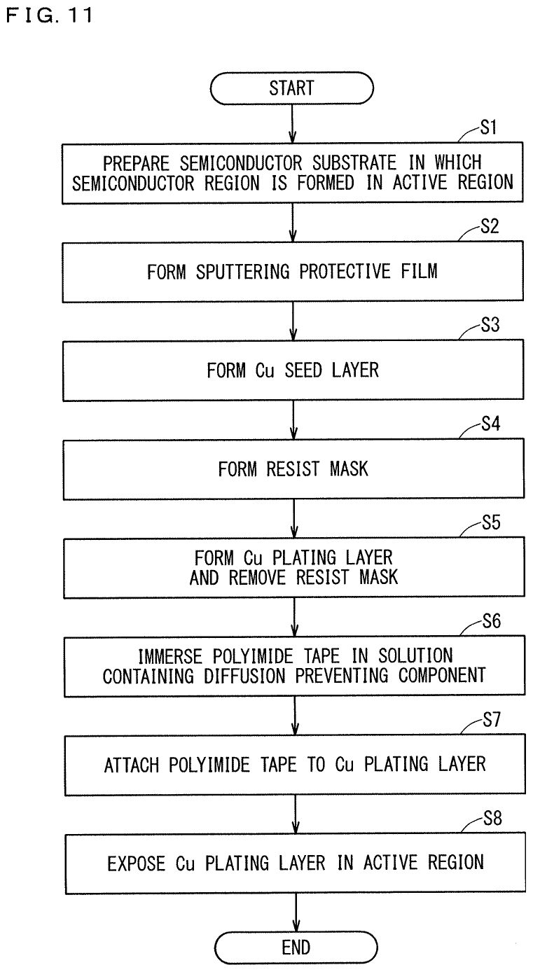

Next, a method of manufacturing the semiconductor device 200 will be described with reference to FIGS. 1 and 12 to 15 using a flowchart indicated in FIG. 11. Note that description of the same processes as those in the flowchart of the first preferred embodiment indicated in FIG. 3 will be omitted.

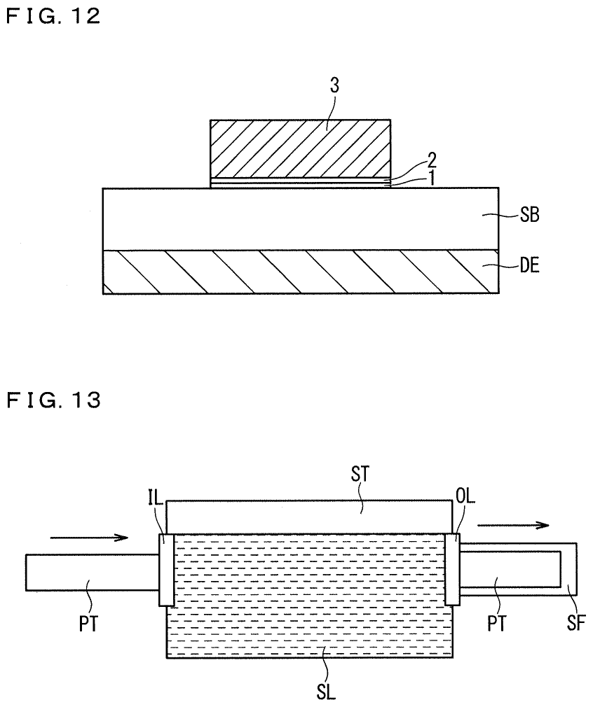

The wafer WF with the copper plating layer 3 formed on the semiconductor substrate SB as illustrated in FIG. 12 is prepared through the steps S1 to S5, and in the step indicated in FIG. 13, the polyimide tape PT formed with a polyimide resin is immersed in the solution SL containing the diffusion preventing component in the processing tank ST (step S10).

As the solution SL containing the diffusion preventing component, a solution containing an organic inhibitor, an inorganic inhibitor, and a metal-containing material such as Ag can be used.

It is only necessary to immerse one surface of the polyimide tape PT in the solution SL, and the polyimide tape PT introduced from an inlet IL of the processing tank ST is sent out from an outlet OL opposite to the inlet IL, but the diffusion preventing component is attached to the back surface of the polyimide tape PT. The polyimide tape has wettability, and thus, the polyimide tape can absorb the diffusion preventing component, and becomes the cap film SF holding the diffusion preventing component by drying. In addition, the resin is not limited to the polyimide resin as long as it can be used as a protective film of a semiconductor device, and other resins such as an acrylic resin and a resin containing polyimide can also be used. Even in these resins, diffusion of copper may occur at the interface with the copper material, and a resin tape to which the diffusion preventing component is attached is effective for preventing diffusion.

Note that the resin tape may have adhesiveness, or may be cured and attached with heat or ultraviolet rays.

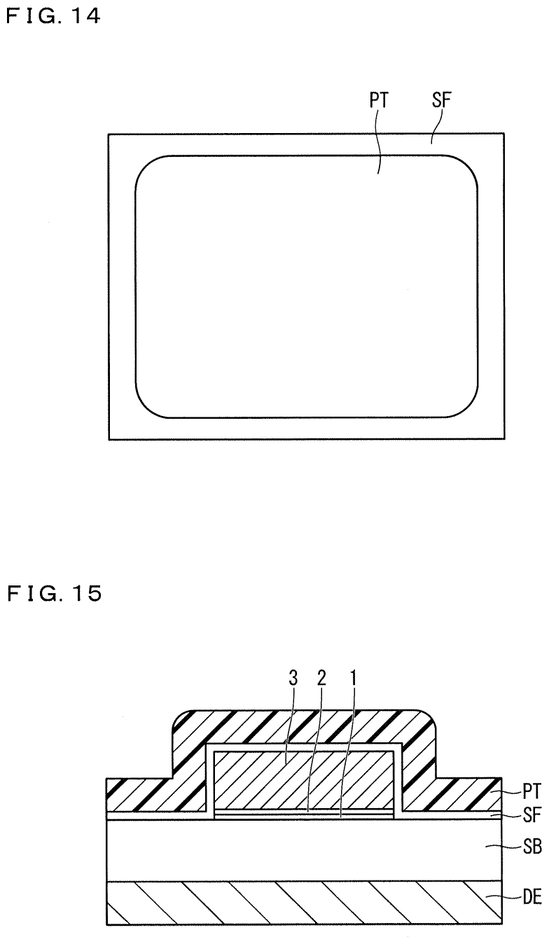

The polyimide tape PT to which the diffusion preventing component is attached is cut in accordance with the shape of the semiconductor device 200 in plan view as illustrated in FIG. 14.

Next, in the process illustrated in FIG. 15, the cut polyimide tape PT is attached onto the copper plating layer 3 on the semiconductor substrate SB. In this event, a lower surface to which the diffusion preventing component is attached is attached so as to be in contact with the copper plating layer 3, whereby the surface of the copper plating layer 3 is covered with the cap film SF (step S11).

Next, the polyimide tape PT is selectively removed together with the cap film SF so as to remain only in a necessary portion, thereby exposing the copper plating layer 3 on the active region AR, that is, the source electrode SE, and obtaining the semiconductor device 200 illustrated in FIG. 10 (step S8).

### Effects

In the semiconductor device 200 according to the second preferred embodiment described above, by attaching the polyimide tape PT to which the diffusion preventing component is attached onto the copper plating layer 3 on the semiconductor substrate SB, the surface of the copper plating layer 3 can be covered with the cap film SF, and only the contact with the copper material can be selectively capped.

Further, the diffusion preventing component is attached to the back surface of the polyimide tape PT on the resin material side. The polyimide tape has wettability, and thus, the polyimide tape can absorb the diffusion preventing component and becomes the cap film SF holding the diffusion preventing component by drying.

In addition, the cap film SF is formed on the resin material side, and thus, the cap film SF does not remain on the metal surface not using the resin and the metal surface from which the resin has been removed. Note that other effects of preventing diffusion are similar to those of the first preferred embodiment.

### Other Application Examples

Although the first and second preferred embodiments described above illustrate examples in which the structure on the substrate according to the present disclosure is applied to a semiconductor device, the structure on the substrate according to the present disclosure can also be applied to a printed circuit board.

In other words, a wiring portion is formed on the printed circuit board by copper plating, and by attaching the polyimide tape to which the diffusion preventing component described in the second preferred embodiment is attached to the wiring portion, a surface of the copper wiring can be covered with the diffusion preventing component, so that it is possible to suppress oxidative decomposition at the interface due to the contact between the polyimide resin and the copper material, suppress oxidation reaction of the copper, and thereby obtain the structure on the substrate in which diffusion of the copper component is prevented, peeling of the resin material is suppressed and reliability is improved.

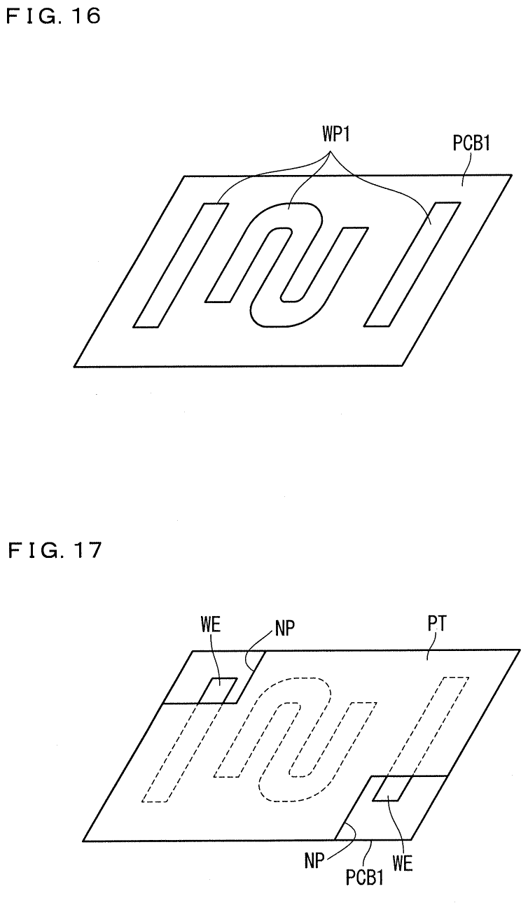

An example in which the structure on the substrate is applied to a printed circuit board will be described with reference to FIGS. 16 to 18. FIG. 16 is a perspective plan view illustrating a printed circuit board PCB1 in a state where a wiring pattern WP1 is formed. In order to form the wiring pattern WP1, a resist mask having an opening corresponding to the pattern of the copper plating layer is formed on the substrate material, copper plating is performed through the opening of the resist mask to form the copper plating layer in the opening, and then the resist mask is removed.

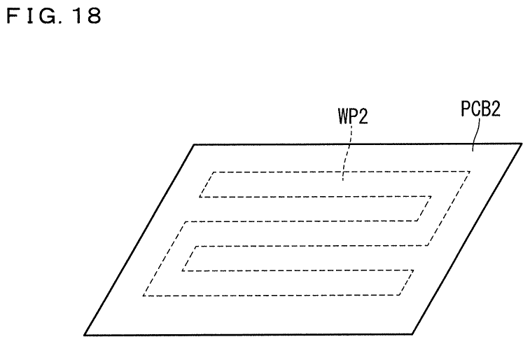

FIG. 17 is a perspective plan view illustrating a state in which the polyimide tape PT having the diffusion preventing component attached thereon is attached onto the printed circuit board PCB1. The polyimide tape PT is provided with a notch portion NP in which the wiring pattern WP1 is exposed, and a wiring end portion WE is exposed in the notch portion NP. As illustrated in FIG. 18, the wiring end portion WE is connected to a wiring pattern WP2 provided on a lower surface of a printed circuit board PCB2 stacked on the printed circuit board PCB1.

As described above, in the printed circuit board having a multilayer structure, by using the polyimide tape in which the diffusion preventing component is attached to the resin material that electrically insulates between the printed circuit boards, it is possible to easily perform capping on the contact point with the copper material, suppress oxidative decomposition at the interface due to the contact between the polyimide resin and the copper material, and suppress oxidation reaction of copper, so that it is possible to obtain the structure on the substrate in which diffusion of the copper component is prevented, peeling of the resin material is suppressed, and reliability is improved.

### Third Preferred Embodiment

In the first preferred embodiment, as described with reference to FIG. 6, the copper plating layer 3 is formed by copper plating in the opening of the resist mask RM, and then the resist mask RM, the seed film 2, and the sputtering protective film 1 are removed. As described with reference to FIG. 7, the wafer WF in a state where the copper plating layer 3 is formed on the semiconductor substrate SB is immersed in the solution SL containing the diffusion preventing component in the processing tank ST to perform capping processing.

As described above, the structure on the substrate of the first preferred embodiment requires a plating process, a resist removal process, and a capping process, and dedicated manufacturing apparatuses are required for each process.

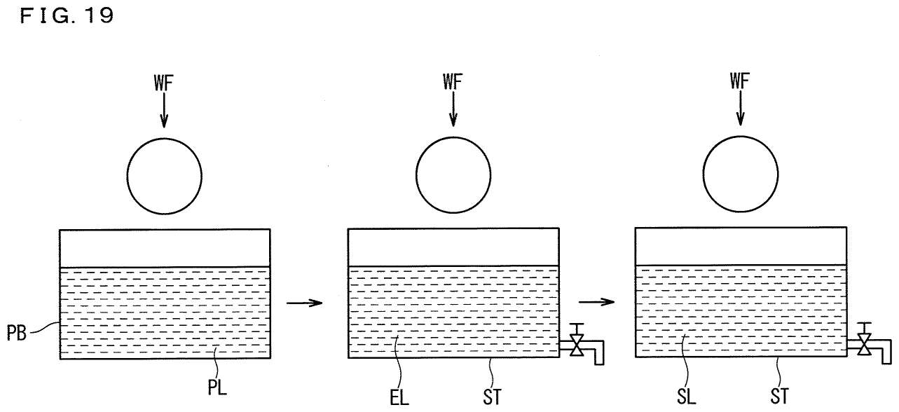

However, in the manufacturing apparatus for the structure on the substrate according to the present disclosure illustrated in FIG. 19, the manufacturing apparatus can be simplified by using the common processing tank ST for the resist removal process and the capping process.

In other words, as illustrated in FIG. 19, first, the wafer WF in a state where the resist mask RM is formed is put into the copper plating solution PL in the plating tank PB, and the copper plating layer 3 is formed by electrolytic plating or electroless plating.

Thereafter, the wafer WF on which the copper plating layer 3 is formed is put into an etching solution EL in the processing tank ST, and the resist mask RM, the seed film 2, and the sputtering protective film 1 are removed by wet etching.

Thereafter, the etching solution EL in the processing tank ST is drained, neutralized, and cleaned, and then, instead, a solution SL containing the diffusion preventing component is injected into the processing tank ST, and the processing tank ST is used as a capping processing tank. The wafer WF on which the copper plating layer 3 is formed is put therein, and the wafer WF is immersed in the solution SL containing the diffusion preventing component to perform capping processing.

As described above, by using the common processing tank ST for the resist removing process and the capping process, the number of manufacturing apparatuses can be reduced, and the manufacturing cost can be reduced.

In addition, by using the common processing tank ST for the resist removing process and the capping process, work is performed at the same place, which eliminates the need for movement to another place and can reduce the number of personnel and processes.

Note that in the present disclosure, the respective embodiments can be freely combined or can be appropriately modified or omitted within the scope of the disclosure.

The present disclosure described above will be collectively described as appendixes.
(Appendix 1)
   A structure on a substrate including:
   a substrate;
   a copper plating layer provided on the substrate;
   a cap film covering the copper plating layer and containing a diffusion preventing component for preventing diffusion of copper; and
a resin film provided on the cap film.
(Appendix 2)
   The structure on the substrate according to Appendix 1, in which the diffusion preventing component includes a long-chain alkyl sulfur compound as an organic inhibitor.
(Appendix 3)
   The structure on the substrate according to Appendix 2, in which the long-chain alkyl sulfur compound is selected from a mercapto compound and a thiourea compound.
(Appendix 4)
   The structure on the substrate according to Appendix 1, in which the diffusion preventing component includes a phosphate compound as an inorganic inhibitor.
(Appendix 5)
   The structure on the substrate according to Appendix 4, in which the phosphate compound is selected from hexametaphosphoric acid, sodium metaphosphate, nitrite, nitrate, chromate, molybdate, technetiate, and vanadate.
(Appendix 6)
   The structure on the substrate according to Appendix 1, in which the diffusion preventing component includes a metal having lower ionization tendency than the copper.
(Appendix 7)
   The structure on the substrate according to any one of Appendixes 1 to 6, in which the resin film includes a polyimide resin or an acrylic resin.
(Appendix 8)
   A method of manufacturing the structure on the substrate according to Appendix 1, the method including:
   (a) a step of preparing a semiconductor substrate as the substrate;
   (b) a step of forming a resist mask having an opening corresponding to a pattern of the copper plating layer on the semiconductor substrate;
   (c) a step of performing copper plating through the opening of the resist mask to form the copper plating layer in the opening;
   (d) a step of removing the resist mask;
   (e) a step of forming the cap film by immersing the semiconductor substrate from which the resist mask has been removed in a solution containing the diffusion preventing component;
   (f) a step of forming the resin film on the cap film; and
   (g) a step of removing the resin film and the cap film at a portion that needs to be exposed in the copper plating layer.
(Appendix 9)
   A method of manufacturing the structure on the substrate according to Appendix 1, the method including:
   (a) a step of preparing a semiconductor substrate as the substrate;
   (b) a step of forming a resist mask having an opening corresponding to a pattern of the copper plating layer on the semiconductor substrate;
   (c) a step of performing copper plating through the opening of the resist mask to form the copper plating layer in the opening;
   (d) a step of removing the resist mask;
   (e) a step of attaching a resin tape immersed in a solution containing the diffusion preventing component to the semiconductor substrate from which the resist mask has been removed such that a surface to which the diffusion preventing component has been attached is on the copper plating layer side, using the diffusion preventing component as the cap film, and using the resin tape as the resin film; and
   (f) a step of removing the resin tape at a portion that needs to be exposed in the copper plating layer together with the cap film.
(Appendix 10)
   A method of manufacturing the structure on the substrate according to Appendix 1, the method including:
   (a) a step of preparing a printed circuit board as the substrate;
   (b) a step of forming a resist mask having an opening corresponding to a pattern of the copper plating layer on the printed circuit board;
   (c) a step of performing copper plating through the opening of the resist mask to form the copper plating layer in the opening;
   (d) a step of removing the resist mask; and
   (e) a step of attaching a resin tape immersed in a solution containing the diffusion preventing component to the printed circuit board from which the resist mask has been removed such that a surface to which the diffusion preventing component is attached is on the copper plating layer side, using the diffusion preventing component as the cap film, and using the resin tape as the resin film.
(Appendix 11)
   The method of manufacturing the structure on the substrate according to Appendix 8, in which the step (e) includes a step of immersing the semiconductor substrate from which the resist mask has been removed in the solution containing a long-chain alkyl sulfur compound that is an organic inhibitor as the diffusion preventing component.
(Appendix 12)
   The method of manufacturing the structure on the substrate according to Appendix 9 or 10, in which the step (e) includes a step of immersing the resin tape in the solution containing a long-chain alkyl sulfur compound that is an organic inhibitor as the diffusion preventing component.
(Appendix 13)
   The method of manufacturing the structure on the substrate according to Appendix 11, in which the long-chain alkyl sulfur compound is selected from a mercapto compound and a thiourea compound.
(Appendix 14)
   The method of manufacturing the structure on the substrate according to Appendix 12, in which the long-chain alkyl sulfur compound is selected from a mercapto compound and a thiourea compound.
(Appendix 15)
   The method of manufacturing the structure on the substrate according to Appendix 8, in which the step (e) includes a step of immersing the semiconductor substrate from which the resist mask has been removed in the solution containing a phosphate compound that is an inorganic inhibitor as the diffusion preventing component.
(Appendix 16)
   The method of manufacturing the structure on the substrate according to Appendix 9 or 10, in which the step (e) includes a step of immersing the resin tape in the solution containing a phosphate compound that is an inorganic inhibitor as the diffusion preventing component.
(Appendix 17)
   The method of manufacturing the structure on the substrate according to Appendix 15, in which the phosphate compound is selected from hexametaphosphate, sodium metaphosphate, nitrite, nitrate, chromate, molybdate, technetiate, and vanadate.
(Appendix 18)
   The method of manufacturing the structure on the substrate according to Appendix 16, in which the phosphate compound is selected from hexametaphosphate, sodium metaphosphate, nitrite, nitrate, chromate, molybdate, technetiate, and vanadate.
(Appendix 19)
   The method of manufacturing the structure on the substrate according to Appendix 8, in which the step (e) includes a step of immersing the semiconductor substrate from which the resist mask has been removed in a solution containing a metal-containing material having lower ionization tendency than copper.
(Appendix 20)
   The method of manufacturing the structure on the substrate according to Appendix 9 or 10, in which the step (e) includes a step of immersing the resin tape in a solution containing a metal-containing material having lower ionization tendency than copper.
(Appendix 21)
   The method of manufacturing the structure on the substrate according to any one of Appendixes 8 to 10, in which the resin film includes a polyimide resin or an acrylic resin.
(Appendix 22)
   A manufacturing apparatus for manufacturing the structure on the substrate according to Appendix 1,
   in which the manufacturing apparatus puts the substrate in a state where a resist mask is formed, into a copper plating solution in a plating tank to form the copper plating layer by electrolytic plating or electroless plating,
   puts the substrate in a state where the copper plating layer is formed, into an etching solution in a processing tank to remove the resist mask by wet etching, and
   changes the processing tank to a capping processing tank by draining the etching solution in the processing tank, cleaning the processing tank, and then injecting a solution containing the diffusion preventing component into the processing tank, puts the substrate in a state where the copper plating layer is formed, into the solution containing the diffusion preventing component, and immerses the substrate in the solution containing the diffusion preventing component to perform capping processing.

While the disclosure has been shown and described in detail, the foregoing description is in all aspects illustrative and not restrictive. It is therefore understood that numerous modifications and variations can be devised.

What is claimed is:

1. A structure on a substrate comprising:
a substrate;
a copper plating layer provided on the substrate;
a cap film covering the copper plating layer and containing a diffusion preventing component for preventing diffusion of copper; and
a resin film provided on the cap film.

2. The structure on the substrate according to claim 1, wherein the diffusion preventing component includes a long-chain alkyl sulfur compound as an organic inhibitor.

3. The structure on the substrate according to claim 2, wherein the long-chain alkyl sulfur compound is selected from a mercapto compound and a thiourea compound.

4. The structure on the substrate according to claim 1, wherein the diffusion preventing component includes a phosphate compound as an inorganic inhibitor.

5. The structure on the substrate according to claim 4, wherein the phosphate compound is selected from hexametaphosphate, sodium metaphosphate, nitrite, nitrate, chromate, molybdate, technetiate, and vanadate.

6. The structure on the substrate according to claim 1, wherein the diffusion preventing component includes a metal having lower ionization tendency than the copper.

7. The structure on the substrate according to claim 1, wherein the resin film includes a polyimide resin or an acrylic resin.

8. A method of manufacturing the structure on the substrate according to claim 1, the method comprising:
(a) a step of preparing a semiconductor substrate as the substrate;
(b) a step of forming a resist mask having an opening corresponding to a pattern of the copper plating layer on the semiconductor substrate;
(c) a step of performing copper plating through the opening of the resist mask to form the copper plating layer in the opening;
(d) a step of removing the resist mask;
(e) a step of forming the cap film by immersing the semiconductor substrate from which the resist mask has been removed in a solution containing the diffusion preventing component; and
(f) a step of forming the resin film on the cap film; and
(g) a step of removing the resin film and the cap film at a portion that needs to be exposed in the copper plating layer.

9. A method of manufacturing the structure on the substrate according to claim 1, the method comprising:
(a) a step of preparing a semiconductor substrate as the substrate;
(b) a step of forming a resist mask having an opening corresponding to a pattern of the copper plating layer on the semiconductor substrate;
(c) a step of performing copper plating through the opening of the resist mask to form the copper plating layer in the opening;
(d) a step of removing the resist mask;
(e) a step of attaching a resin tape immersed in a solution containing the diffusion preventing component to the semiconductor substrate from which the resist mask has been removed such that a surface on which the diffusion preventing component adheres is on the copper plating layer side, using the diffusion preventing component as the cap film, and using the resin tape as the resin film; and
(f) a step of removing the resin tape at a portion that needs to be exposed in the copper plating layer together with the cap film.

10. A method of manufacturing the structure on the substrate according to claim 1, the method comprising:
(a) a step of preparing a printed circuit board as the substrate;
(b) a step of forming a resist mask having an opening corresponding to a pattern of the copper plating layer on the printed circuit board;
(c) a step of performing copper plating through the opening of the resist mask to form the copper plating layer in the opening;
(d) a step of removing the resist mask; and
(e) a step of attaching a resin tape immersed in a solution containing the diffusion preventing component to the printed circuit board from which the resist mask has been removed such that a surface to which the diffusion preventing component is attached is on the copper plating layer side, using the diffusion preventing component as the cap film, and using the resin tape as the resin film.

11. The method of manufacturing the structure on the substrate according to claim 8, wherein the step (e) includes a step of immersing the semiconductor substrate from which the resist mask has been removed in the solution containing a long-chain alkyl sulfur compound that is an organic inhibitor as the diffusion preventing component.

12. The method of manufacturing the structure on the substrate according to claim 9, wherein the step (e) includes a step of immersing the resin tape in the solution containing a long-chain alkyl sulfur compound that is an organic inhibitor as the diffusion preventing component.

13. The method of manufacturing the structure on the substrate according to claim 10, wherein the step (e) includes a step of immersing the resin tape in the solution containing a long-chain alkyl sulfur compound that is an organic inhibitor as the diffusion preventing component.

14. The method of manufacturing the structure on the substrate according to claim 11, wherein the long-chain alkyl sulfur compound is selected from a mercapto compound and a thiourea compound.

15. The method of manufacturing the structure on the substrate according to claim 12, wherein the long-chain alkyl sulfur compound is selected from a mercapto compound and a thiourea compound.

16. The method of manufacturing the structure on the substrate according to claim 13, wherein the long-chain alkyl sulfur compound is selected from a mercapto compound and a thiourea compound.

17. The method of manufacturing the structure on the substrate according to claim 8, wherein the step (e) includes a step of immersing the semiconductor substrate from which the resist mask has been removed in the solution containing a phosphate compound that is an inorganic inhibitor as the diffusion preventing component.

18. The method of manufacturing the structure on the substrate according to claim 9, wherein the step (e) includes a step of immersing the resin tape in the solution containing a phosphate compound that is an inorganic inhibitor as the diffusion preventing component.

19. The method of manufacturing the structure on the substrate according to claim 10, wherein the step (e) includes a step of immersing the resin tape in the solution containing a phosphate compound that is an inorganic inhibitor as the diffusion preventing component.

20. The method of manufacturing the structure on the substrate according to claim 17, wherein the phosphate compound is selected from hexametaphosphate, sodium metaphosphate, nitrite, nitrate, chromate, molybdate, technetiate, and vanadate.

21. The method of manufacturing the structure on the substrate according to claim 18, wherein the phosphate compound is selected from hexametaphosphate, sodium metaphosphate, nitrite, nitrate, chromate, molybdate, technetiate, and vanadate.

22. The method of manufacturing the structure on the substrate according to claim 19, wherein the phosphate compound is selected from hexametaphosphate, sodium metaphosphate, nitrite, nitrate, chromate, molybdate, technetiate, and vanadate.

23. The method of manufacturing the structure on the substrate according to claim 8, wherein the step (e) includes a step of immersing the semiconductor substrate from which the resist mask has been removed in a solution containing a metal-containing material having lower ionization tendency than copper.

24. The method of manufacturing the structure on the substrate according to claim 9, wherein the step (e) includes a step of immersing the resin tape in a solution containing a metal-containing material having lower ionization tendency than copper.

25. The method of manufacturing the structure on the substrate according to claim 10, wherein the step (e) includes a step of immersing the resin tape in a solution containing a metal-containing material having lower ionization tendency than copper.

26. The method of manufacturing the structure on the substrate according to claim 8, wherein the resin film includes a polyimide resin or an acrylic resin.

27. The method of manufacturing the structure on the substrate according to claim 9, wherein the resin film includes a polyimide resin or an acrylic resin.

28. The method of manufacturing the structure on the substrate according to claim 10, wherein the resin film includes a polyimide resin or an acrylic resin.
